(19) United States
(12) Patent Application Publication
(10) Pub. No.: US 2026/0013057 A1
(43) Pub. Date: Jan. 8, 2026

(54) ROTATING DISPLAY DEVICE

(71) Applicant: Shenzhen Beipengxing Technology Co., Ltd., Shenzhen (CN)

(72) Inventor: Chunli Xu, Shenzhen (CN)

(21) Appl. No.: 19/259,143

(22) Filed: Jul. 3, 2025

(30) Foreign Application Priority Data
Jul. 5, 2024 (CN) 202421602789.3

(51) Int. Cl. H05K 5/02

(52) U.S. Cl. CPC H05K 5/0217

(57) ABSTRACT

A rotating display device includes a housing defining an accommodating space, a base, and a rotating driving assembly. The accommodating space includes a first space and a second space communicated with the first space. A portion of the housing defining the first space is made of a light-transmitting material. A boss is disposed at a bottom portion of the housing. The second space is defined inside the boss. The first space accommodates a main body of a display piece. The second space accommodates a bottom portion of the display piece. A mounting opening is defined in a top portion of the base. The rotating driving assembly is disposed in the base. The boss extends into the mounting opening to be fixedly connected to an output shaft of the rotating driving assembly. The rotating driving assembly is configured to drive the housing to rotate relative to the base.

### TECHNICAL FIELD

The present disclosure relates to a technical field of display stands, and in particular to a rotating display device.

### BACKGROUND

Rotating display devices are devices configured to display display pieces, which increase a display effect and a viewing experience by rotating. The rotating display devices are commonly configured to display small items such as artworks, figurines, models, jewelry, etc. A structural design of the rotating display devices allows viewers to view exhibits from multiple angles, thereby providing a comprehensive and attractive viewing experience.

In order to improve the viewing experience of the viewers, the display pieces gradually become diversified. For example, when displaying a figurine, some users may choose to plant small herbs in a bottom area of the figurine to enrich the artistic beauty of the figurine. However, soil placed on the bottom area of the figurine, where the small herbs are planted is exposed within a display range, thereby affecting the beauty of the figurine.

However, a conventional rotating display device is unable to display only a portion of the display piece that needs to be displayed. For example, the conventional rotating display device is unable to only display a portion of the figurine above the soil.

Therefore, it is urgent to provide a rotating display device with a simple structure and low cost, which can realize the display of only the part of the display piece that needs to be displayed.

### SUMMARY

In view of problems in the prior art, one embodiment of the present disclosure provides a rotating display device with a simple structure and low cost. After a display piece is loaded, the rotating display frame is driven to drive the display piece to rotate for display, while hiding a bottom portion of the display piece and only displaying a main body of the display piece.

The rotating display device comprises a housing, a base, and a rotating driving assembly. An accommodating space is defined in the housing. The accommodating space comprises a first space and a second space communicated with the first space. At least a portion of the housing defining the first space is made of a light-transmitting material. A boss is disposed at a bottom portion of the housing. The second space is defined inside the boss. The first space is configured to accommodate a main body of a display piece. The second space is configured to accommodate a bottom portion of the display piece.

A mounting opening is defined in a top portion of the base. The rotating driving assembly is disposed in the base. The boss extends into the mounting opening to be fixedly connected to an output shaft of the rotating driving assembly. The rotating driving assembly is configured to drive the housing to rotate relative to the base, so as to drive the display piece to rotate.

In one optional embodiment, the rotating display device further comprises a mounting base. The mounting base is disposed in the base and is in a box shape with an opening facing the mounting opening. A bottom portion of the mounting base is fixedly connected to the output shaft of the rotating driving assembly. The boss is inserted and fixed inside the mounting base.

In one optional embodiment, a limiting groove is defined in a center of an inner bottom surface of the base. Positioning columns are distributed on the inner bottom surface of the base. The positioning columns are disposed around the limiting groove. The rotating driving assembly comprises a rotating column, a transmission gear set, and a driving piece.

A first end of the rotating column is rotatably disposed in the limiting groove. A second end of the rotating column is fixed to a center of a bottom surface of the mounting base.

The transmission gear set comprises an input gear, transmission gears and an output gear. The input gear, the transmission gears, and the output gear are sequentially engaged. The input gear and the transmission gears are respectively rotatably sleeved on the positioning columns. The output gear is fixedly sleeved on the rotating column. The driving piece comprises the output shaft. The output shaft is connected to the input gear and is configured to drive the input gear to rotate, transmission gears rotate to drive the output gear to rotate, the output gear rotates to drive the rotating column to rotate, and the rotating column rotates to drive the mounting base to rotate.

In one optional embodiment, the driving piece is horizontally disposed in the base, and the output shaft is rotatably and vertically connected to the input gear.

In one optional embodiment, top ends of the positioning columns are fixedly connected to a support platform. A through hole is defined in the support platform. The mounting base is disposed on the support platform. The rotating column passes through the through hole and is fixed in the center of the bottom surface of the mounting base. The rotating column is configured to drive the mounting base to rotate on the support platform.

In one optional embodiment, rims are disposed on a top surface of the support platform. The rims have a same length and are centrosymmetric. The mounting base is disposed on the rims. The rotating column is configured to drive the mounting base to rotate on the rims.

In one optional embodiment, light-emitting pieces are embedded on the top portion of the base and are disposed around the mounting opening. The light-emitting pieces are configured to emit light toward the first space.

In one optional embodiment, at least part of the light-emitting pieces are configured to alternately emit light of at least two colors.

In one optional embodiment, the bottom portion of the housing is detachably connected to a side wall of the housing, and/or a top surface of the housing is detachably connected to the side wall of the housing.

In one optional embodiment, the accommodating space is further configured to hold a transparent liquid, and the display piece is submerged in the transparent liquid.

In the embodiment of the present disclosure, the boss disposed at the bottom portion of the housing is extended into the mounting opening and fixedly connected to the output shaft of the rotating driving assembly, and the display piece is fixed in the second space defined inside the boss, so as to obtain the rotating display device. An assembly process of the rotating display device is relatively easy. Under the drive of the rotating driving assembly, the rotating display device drives the housing and the display piece to rotate together through the boss. The first space accommodates the main body of the display piece, and the second space accommodates the bottom portion of the display piece, so that the bottom portion of the display piece is hidden by a portion of the housing forming the second space, and the main body of the display piece is allowed to be displayed by the portion of the housing made of the light-transmitting material that forms the first space, so that only the main body of the display piece located in the first space is displayed. In addition, the boss acts as a transmission piece of the output shaft of the rotating driving assembly, driving the housing and the display piece to rotate, and at the same time, the second space of the boss shields the bottom portion of the display piece, which simplifies a structure of the rotating display device. Therefore, the rotating display device is simple in structure, low in design cost, and easy to produce.

The above description is merely an overview of technical solutions of the present disclosure. In order to clearly understand technical means of the present disclosure and enable the present disclosure being implemented according to a content of the description, and in order to make the above and other objectives, features and characteristics of the present disclosure obvious and understandable, specific embodiments of the present disclosure are described below.

### BRIEF DESCRIPTION OF DRAWINGS

Various characteristics and benefits will become obvious to those skilled in the art by reading following detailed description of optional embodiments. Drawings are only for a purpose of illustrating the optional embodiments and are not considered to be limiting of the present disclosure. Moreover, in all of the drawings, same reference symbols refer to the same components.

FIG. 1 is a front side schematic diagram of a rotating display device according to one embodiment of the present disclosure.

FIG. 2 is an exploded schematic diagram of the rotating display device according to one embodiment of the present disclosure.

FIG. 3 is an exploded schematic diagram of a housing according to one embodiment of the present disclosure.

FIG. 4 is a cross-sectional schematic diagram of the rotating display device shown in FIG. 1.

FIG. 5 is an enlarged schematic diagram of portion A shown in FIG. 4.

FIG. 6 is a top plan schematic diagram of a rotating driving assembly according to one embodiment of the present disclosure.

FIG. 7A is a partially exploded schematic diagram of the rotating display device according to one embodiment of the present disclosure, where the housing, a mounting base, a support platform, and the rotating driving assembly are shown.

FIG. 7B is another partially exploded schematic diagram of the rotating display device according to one embodiment of the present disclosure, where the housing, the mounting base, the support platform, and the rotating driving assembly are shown.

FIG. 8 is a front side schematic diagram of a boss and light-emitting pieces according to one embodiment of the present disclosure.

FIG. 9 is a bottom schematic diagram of the boss according to one embodiment of the present disclosure.

1—rotating display device; 10—housing; 10a—bottom portion of the housing; 10b—side wall of the housing; 10c—top surface of the housing; 11—accommodating space; 111—first space; 112—second space; 12—boss; 20—base; 21—mounting opening; 22—limiting groove; 231˜233—positioning columns; 241—first button; 242—second button; 243—third button; 30—rotating driving assembly; 31—rotating column; 321—input gear; 322—output gear; 3231˜3233—transmission gears; 33—driving piece; 331—output shaft; 40—mounting base; 50—support platform; 51—through hole; 521˜522—rims; 60—light-emitting fixing piece; 61˜63—light-emitting pieces.

### DETAILED DESCRIPTION

The following describes embodiments of technical solutions of the present disclosure in detail with reference to the accompanying drawings. The following embodiments are merely configured to describe the technical solutions of the present disclosure clearly, and are therefore merely examples, which do not limit the protection scope of the present disclosure.

Unless otherwise defined, all technical and scientific terms used herein have the same meaning as commonly understood by those skilled in the art of the present disclosure. The terms used in the description of the present disclosure herein are only for the purpose of describing specific embodiments, and are not intended to limit the present disclosure. In the specification and claims of the present disclosure, terms “comprise”, “have”, and any variations thereof are intended to cover non-exclusive inclusion.

In the description of the embodiments of the present disclosure, the technical terms “first”, “second”, etc., are merely configured to distinguish different objects, and cannot be understood as indicating or implying relative importance or implicitly indicating a quantity, a specific order, or a primary and secondary relationship of the indicated technical features. In the description of the embodiments of the present disclosure, “a plurality of” means two or more, unless specified otherwise.

Reference herein to “embodiment” means that a particular feature, structure, or characteristic described in connection with one embodiment may be comprised in at least one embodiment of the present disclosure. The appearances of the “embodiment” in various positions in the specification are not necessarily referring to the same embodiment, and are not independent or alternative embodiments mutually exclusive of other embodiments. Those skilled in the art explicitly and implicitly understand that the embodiments described herein may be combined with other embodiments.

In the description of the embodiments of the present disclosure, the term “and/or” depicts relationships between associated objects and there are three relationships thereon. For example, A and/or B may indicate A exists alone, A and B exist at the same time, and B exists alone. The character “/” generally indicates that the associated object is alternative. The terms “first”, “second”, “third”, etc. in the present disclosure are used only to distinguish similar objects and do not imply a specific ordering of objects.

In the description of the embodiments of the present disclosure, the term “a plurality of” means two or more. Similarly, “multiple groups” refers to more than two groups (including two groups), and “multiple pieces” refers to more than two pieces (including two pieces).

It should be understood that in the description of the present disclosure terms such as “central”, “lateral”, “lengthways”, “length”, “width”, “thickness”, “upper”, “lower”, “left”, “right”, “vertical”, “horizontal”, “top”, “bottom”, “inner”, “outer”, “clockwise”, “counterclockwise”, “radial”, “axial”, “circumferential”, etc. indicate direction or position relationships shown based on the drawings, and are only intended to facilitate the description of the present disclosure and the simplification of the description rather than to indicate or imply that the indicated device or element must have a specific direction or constructed and operated in a specific direction, and therefore, shall not be understood as a limitation to the present disclosure.

It should be noted in the description of the present disclosure that, unless otherwise regulated and defined, terms such as “installation,” “bonded,” and “connection” shall be understood in a broad sense, and for example, may refer to fixed connection or detachable connection or integral connection; may refer to mechanical connection or electrical connection; and may refer to direct connection or indirect connection through an intermediate medium or inner communication of two elements. For those of ordinary skill in the art, the meanings of the above terms in the present disclosure may be understood according to concrete conditions.

In view of problems in the prior art, the inventor of the present disclosure found that a bottom area of a display piece is allowed to be hidden so that it is not exposed to the field of vision of a viewer. As a result, only a main body of the display piece is displayed. Specifically, a boss is disposed at a bottom portion of the housing for accommodating the display piece, so that a second space is defined inside the boss, and a first space communicated with the first space is formed inside the housing.

The first space accommodates the main body of the display piece, and the second space accommodates a bottom portion of the display piece, so that the bottom portion of the display piece is hidden by a portion of the housing forming the second space, and the main body of the display piece is allowed to be displayed through a portion of the housing made of a light-transmitting material that forms the first space, so that only the main body of the display piece located in the first space is displayed.

Furthermore, in order to achieve a rotating display function of the rotating display device, the boss disposed at the bottom portion of the housing is extended into a mounting opening and fixedly connected to an output shaft of a rotating driving assembly, and the display piece is fixed in the second space defined inside the boss, so that under the drive of the rotating driving assembly, the rotating display device drives the housing and the display piece to rotate together through the boss. Therefore, the boss acts as a transmission piece of the output shaft of the rotating driving assembly, driving the housing and the display piece to rotate, and at the same time, the second space of the boss shields the bottom portion of the display piece, which simplifies a structure of the rotating display device. Therefore, the rotating display device is simple in structure, low in design cost, and easy to produce.

The present disclosure is applicable to displaying the display piece, and the display may be a single collection, a composite collection formed by a combination of a plurality of collections, or the display formed by a combination of the collection and auxiliary materials (such as herbal plants, specimens, landscape models, etc.).

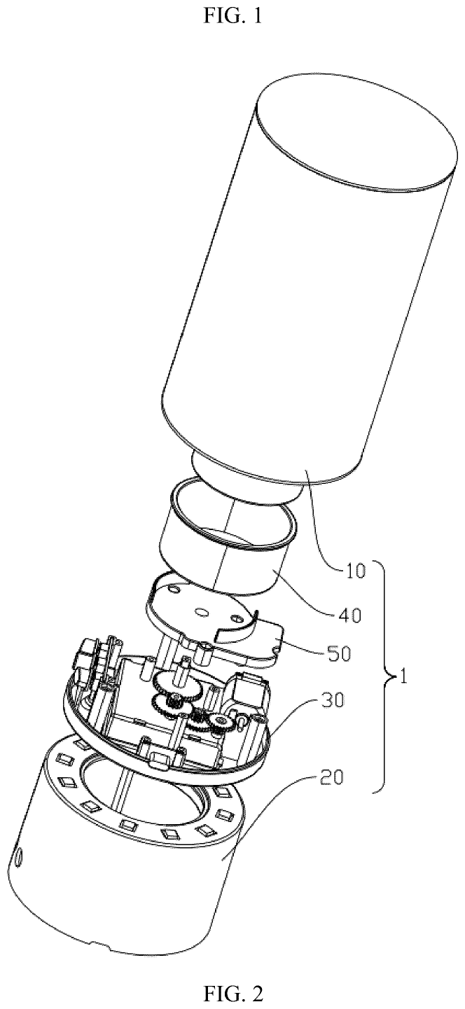

Specifically, as shown in FIGS. 1-5, the rotating display device 1 comprises a housing 10, a base 20, and a rotating driving assembly 30. An accommodating space 11 is defined in the housing 10. The accommodating space 11 comprises a first space 111 and a second space 112 communicated with the first space 111. At least a portion of the housing 10 defining the first space 111 is made of a light-transmitting material. A boss 12 is disposed at a bottom portion of the housing 10, and the second space 112 is defined inside the boss 12. The first space 111 is configured to accommodate the main body of the display piece. The second space 112 is configured to accommodate the bottom portion of the display piece.

A mounting opening 21 is defined in a top portion of the base 20. The rotating driving assembly 30 is disposed in the base 20. The boss 12 extends into the mounting opening 21 to be fixedly connected to an output shaft of the rotating driving assembly 30. The rotating driving assembly 30 is configured to drive the housing 10 to rotate relative to the base 20. The housing 10 is driven by the rotating driving assembly 30 to drive the display piece to rotate.

Optionally, the first space 111 and the second space 112 of the housing 10 are two cylindrical cavities of different sizes with collinear center lines, so as to improve overall stability of the rotating display device 1 when rotating the display piece.

The bottom portion of the display piece is bonded or welded to the bottom portion of the boss 12, so that the second space 112 is configured to accommodate the bottom portion of the display piece. Optionally, the display piece is sleeved in the boss 12 to effectively offset a centrifugal force exerted on the display piece during a rotation process, thereby preventing the display piece from being displaced relative to the boss 12 under the centrifugal force generated during the rotation process. Therefore, the display piece is prevented from being damaged.

The first space 111 may be filled as needed. For instance, a mountain model may be fixed in the first space 111, thereby improving the aesthetics of the rotating display device 1. The second space 112 is matched with the display piece, so that the display piece is inserted and fixed in the second space 112 and fills the second space 112, thereby improving the stability of the display piece during the rotation process for displaying.

Optionally, the accommodating space 11 is further configured to hold a transparent liquid, and the display piece is submerged in the transparent liquid.

The transparent liquid is selected according to actual use needs. For instance, when the display piece is submerged with water, some organisms (such as water plants and small freshwater shrimps) are in the accommodating space 11 to increase the interest of the rotating display device 1. Alternatively, since glycerol is not easy to volatilize and has a high refractive index, when the display piece is submerged in the glycerol, a frequency of replacement and addition of the glycerol in the accommodating space 11 is reduced. Alternatively, when the display piece comprises a biological specimen, the display piece is submerged in formalin to prolong service life of the display.

In order to improve a convenience of replacing the transparent liquid in the accommodating space 11, as shown in FIG. 3, a top surface 10c of the housing 10 is detachably connected to a side wall 10b of the housing 10.

For instance, the top surface 10c of the housing is screwed to the side wall 10b of the housing by threads thereon, so that the top surface of the housing is disassembled from the side wall 10b of the housing by rotating. Alternatively, the top surface 10c of the housing is sleeved on the side wall 10b of the housing through a first sealing ring, so that the top surface 10c of the housing and the side wall 10b of the housing are disassembled by applying an external force in an opposite direction to a sleeve connection direction. When the transparent liquid is poured into the accommodating space 11, the top surface 10c of the housing is separated from the side wall 10b of the housing.

As shown in FIG. 3 the bottom portion 10a of the housing 10 is detachably connected to the side wall 10b of the housing 10.

Similarly, the bottom portion 10a of the housing is screwed to the side wall 10b of the housing through threads thereon, so that when the display piece needs to be installed or replaced, the bottom portion 10a of the housing is disassembled from the side wall 10b of the housing by rotating the bottom portion 10a of the housing, thereby improving the convenience of installing the display piece. Alternatively, the side wall 10b of the housing is sleeved to the bottom portion 10a of the housing through a second sealing ring, so that when the display piece needs to be installed or replaced, the side wall 10b of the housing is disassembled from the bottom portion 10a of the housing by applying an external force in an opposite direction of a sleeve connection direction of the bottom portion and the side wall of the housing, thereby improving the convenience of installing the display piece.

Furthermore, the side wall 10b and the top surface 10c of the housing are made of the light-transmitting material, such as polymethyl methacrylate, polyethylene terephthalate, etc. The bottom portion 10a of the housing and the boss 12 are made of an opaque material, such as metal, ceramic, etc., so that the viewer is able to appreciate the main body of the display piece.

A shape of the base 20 is not limited, and the base 20 may be a cylinder or a cube, which is designed according to actual needs.

Optionally, the boss 12 is a hollow cylinder, and the mounting opening 21 is a circular opening. Shapes of the boss 12 and the mounting opening 21 are matched with each other, so that the boss 12 is allowed to rotate in the mounting opening 21.

Optionally, the rotating driving assembly 30 is bonded or welded to the bottom portion of the base 20.

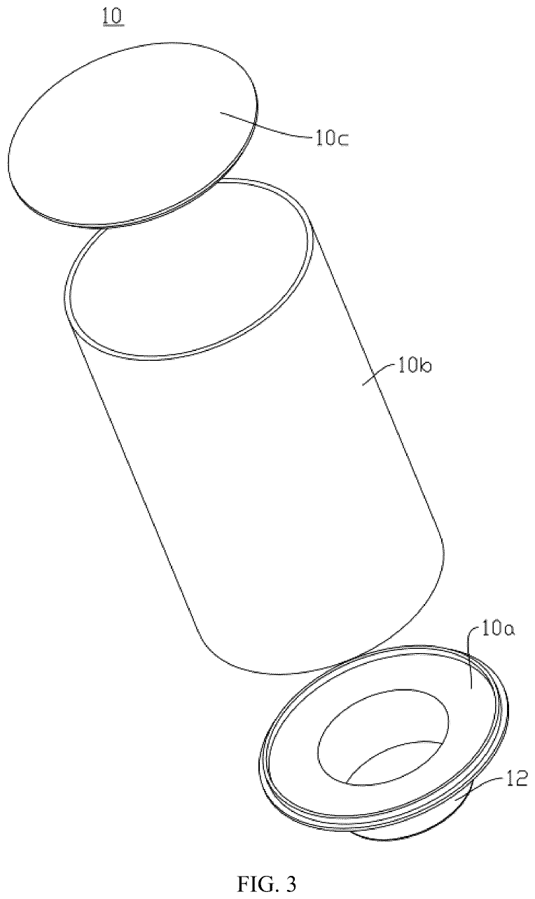

As shown in FIGS. 2, 4, and 5, the rotating display device 1 further comprises a mounting base 40. The mounting base 40 is disposed inside the base 20 and is in a box shape with an opening facing the mounting opening 21. A bottom portion of the mounting base 40 is fixedly connected to the output shaft of the rotating driving assembly 30. The boss 12 is inserted and fixed inside the mounting base 40.

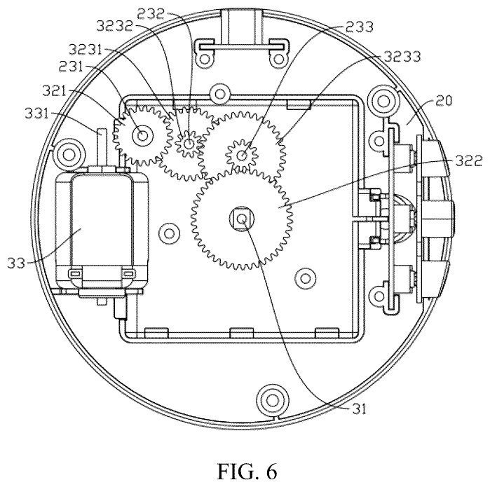

FIG. 6 is a top plan schematic diagram of the rotating driving assembly according to one embodiment of the present disclosure.

As shown in FIGS. 5-6, a limiting groove 22 is defined in a center of an inner bottom surface of the base 20. Positioning columns 231-233 are distributed on the inner bottom surface of the base 20. The positioning columns 231-233 are disposed around the limiting groove 22. The rotating driving assembly 30 comprises a rotating column 31, a transmission gear set, and a driving piece 33. A first end of the rotating column 31 is rotatably disposed in the limiting groove 22. A second end of the rotating column 31 is fixed to a center of a bottom surface of the mounting base 40. The transmission gear set comprises an input gear 321, transmission gears 3231-3233 and an output gear 322. The input gear 321, the transmission gears 3231-3233, and the output gear 322 are sequentially engaged. The input gear 321 and the transmission gears 3231-3233 are respectively rotatably sleeved on the positioning columns 231-233. The output gear 322 is fixedly sleeved on the rotating column 31. The driving piece 33 is a motor. The driving piece 33 comprises the output shaft 331. The output shaft 331 is connected to the input gear 321 and is configured to drive the input gear 321 to rotate. The input gear 321 is configured to drive the output gear 322 to rotate under the transmission of the transmission gears 3231-3233. The output gear 322 is configured to drive the rotating column 31 to rotate under the drive of the driving piece 33. The rotating column 31 is configured to drive the mounting base 40 to rotate under the drive of the driving piece 33.

Optionally, the mounting base 40 is screwed to the rotating column 31 through threads, and a rotation direction of the thread of the rotating column 31 is consistent with a rotation direction of the rotating column 31, so as to avoid a connection between the mounting base 40 and the rotating column 31 from loosening due to the rotation of the rotating column 31, thereby improving the connection stability between the mounting base 40 and the rotating column 31.

As shown in FIGS. 2, 4, 5 and 6, the bottom portion of the mounting base 40 is fixedly connected to the rotating column 31 of the rotating driving assembly 30, and an opening of the mounting base 40 faces the boss 12 to accommodate the boss. During assembly, it is only necessary to extend the boss 12 into the mounting opening 21 and insert and fix the boss 12 inside the mounting base 40 to complete an assembly between the housing 10 and the rotating driving assembly 30, thereby further reducing the difficulty of assembling the housing 10. Further, the boss 12 is inserted and fixed inside the mounting base 40, which is not only convenient for assembly, but also the centrifugal force applied to the boss 12 during rotation is offset by a side wall of the mounting base 40, thereby avoiding displacement of the boss 12 relative to the rotating driving assembly 30 during the rotation process, thereby improving the reliability of the rotating display device 1.

The output shaft 331 of the driving piece 33 is connected to the input gear 321 of the transmission gear set to drive the input gear 321 of the transmission gear set to rotate. The input gear 321 drives the output gear 322 to rotate through the transmission of the transmission gears 3231-3233. The output gear 322 drives the rotating column 31 to rotate under the drive of the driving piece 33. The rotating column 31 drives the mounting base 40 to rotate under the drive of the driving piece 33. Since the input gear 321, the transmission gears 3231-3233 and output gear 322 of the transmission gear set are engaged in sequence, an output of the driving piece 33 with high speed and low torque is converted into an output of the output gear 322 with low speed and high torque, so that the rotating column 31 is driven to rotate at a low speed through the output gear 322, so as to realize a low-speed rotation of the display piece and improve a viewing experience of the viewer.

The input gear 321 and the transmission gears 3231-3233 are respectively rotatably sleeved on the positioning columns 231˜233, the output gear 322 is fixedly sleeved on the rotating column 31, and the first end of the rotating column 31 is rotatably inserted into the limiting groove 22, so that when the input gear, the transmission gears, and the output gear in the transmission gear set are engaged and moved, so the rotating driving assembly is not easy to be displaced, thereby improving the stability of the rotating display device 1.

Optionally, as shown in FIG. 6, the driving piece 33 is horizontally disposed in the base 20, and the output shaft 331 is rotatably and vertically connected to the input gear 321.

The output shaft 331 of the driving piece 33 is rotatably and vertically connected to the input gear 321 in the transmission gear set through a transmission structure, and the transmission structure is a worm gear mechanism, a bevel gear transmission structure, etc.

The driving piece 33 is horizontally disposed inside the base 20, and the output shaft 331 of the driving piece 33 is vertically connected to the input gear 321 of the transmission gear set, which reduces an occupied pace of the rotating driving assembly in the base 20, thereby reducing a volume of the rotating display device 1 and realizing miniaturization of the rotating display device.

When a mass of the housing 10 and the display piece is heavy, it is necessary to ensure that a horizontal surface of the housing 10 remains horizontal during the rotation process to avoid malfunction of the rotating display device 1.

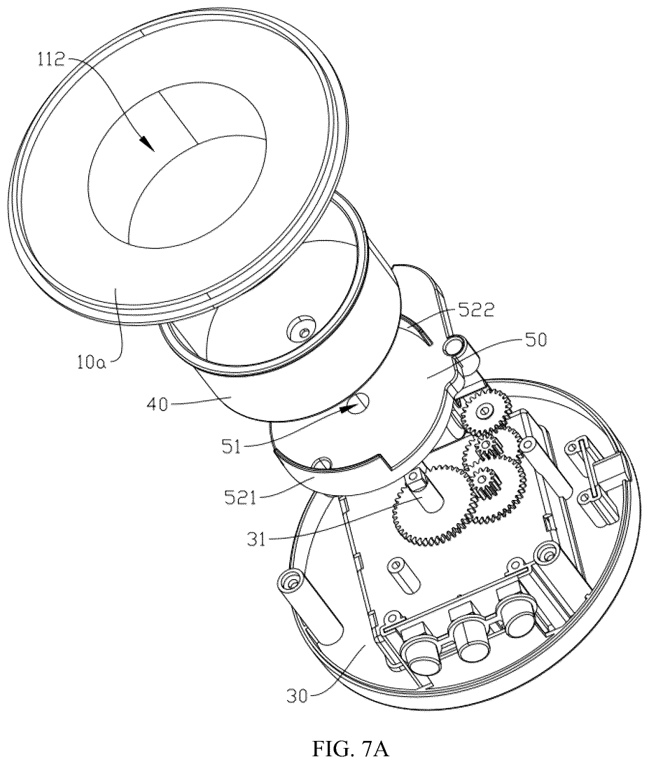

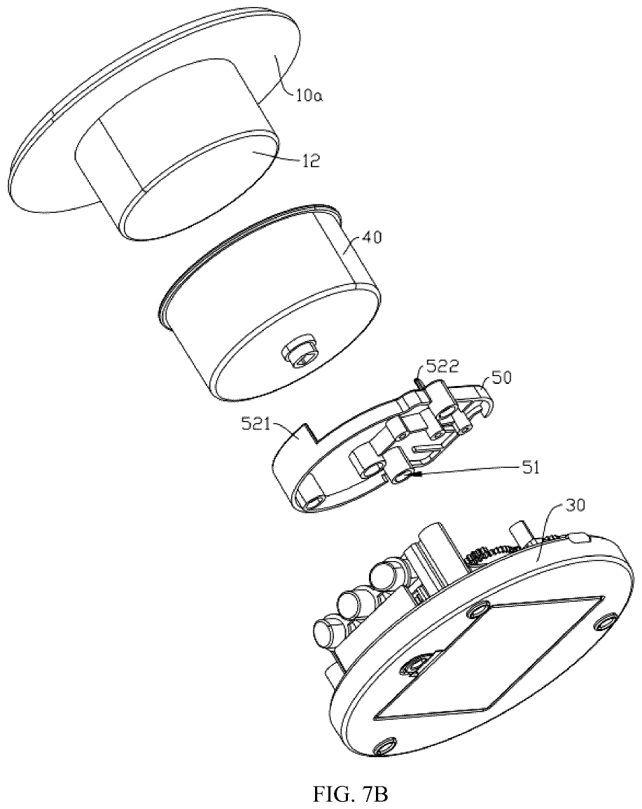

FIG. 7A is a partially exploded schematic diagram of the rotating display device according to one embodiment of the present disclosure, where the housing, the mounting base, a support platform 50, and the rotating driving assembly are shown. FIG. 7B is another partially exploded schematic diagram of the rotating display device according to one embodiment of the present disclosure, where the housing, the mounting base, the support platform 50, and the rotating driving assembly are shown. As shown in FIGS. 6, 7A and 7B, in order to ensure that the horizontal surface of the housing 10 remains horizontal during the rotation process, top ends of the positioning columns 231-233 are fixedly connected to a support platform 50. A through hole 51 is defined in the support platform 50. The mounting base 40 is disposed on the support platform 50. The rotating column 31 passes through the through hole 51 and is fixed in the center of the bottom surface of the mounting base 40. The rotating column 31 is configured to drive the mounting base 40 to rotate on the support platform 50.

Optionally, connecting grooves (not shown in the drawings) are defined in a bottom surface of the support platform 50. The top ends of the positioning columns 231-233 are respectively inserted and fixed in the connecting grooves on the bottom surface of the support platform 50, so that the support platform 50 is simple in structure and easy to install.

The mounting base 40 is disposed on the support platform 50, and the rotating column 31 passes through the through hole 51 of the support platform 50 and is fixed to the center of the bottom surface of the mounting base 40. The rotating column 31 drives the mounting base 40 to rotate on the support platform 50. The support platform 50 and the positioning columns 231-233 are further configured to support the housing 10 and the display piece, thereby improving support stability of the housing 10 and the display piece.

Optionally, to reduce friction resistance between the mounting base 40 and the support platform 50, rims 521-522 are disposed on a top surface of the support platform 50. The rims 521-522 have a same length and are centrosymmetric. The mounting base 40 is disposed on the rims 521-522. The rotating column 31 is configured to drive the mounting base 40 to rotate on the rims 521-522.

On the top surface of the support platform 50, the rims 521-522 are symmetrically disposed with respect to the center of the top surface of the support platform 50, and the rims 521-522 contact the bottom surface of the mounting base 40, so that a contact area between the mounting base 40 and the support platform 50 reduces, thereby effectively reducing the friction resistance of the support platform 50 during the rotation process.

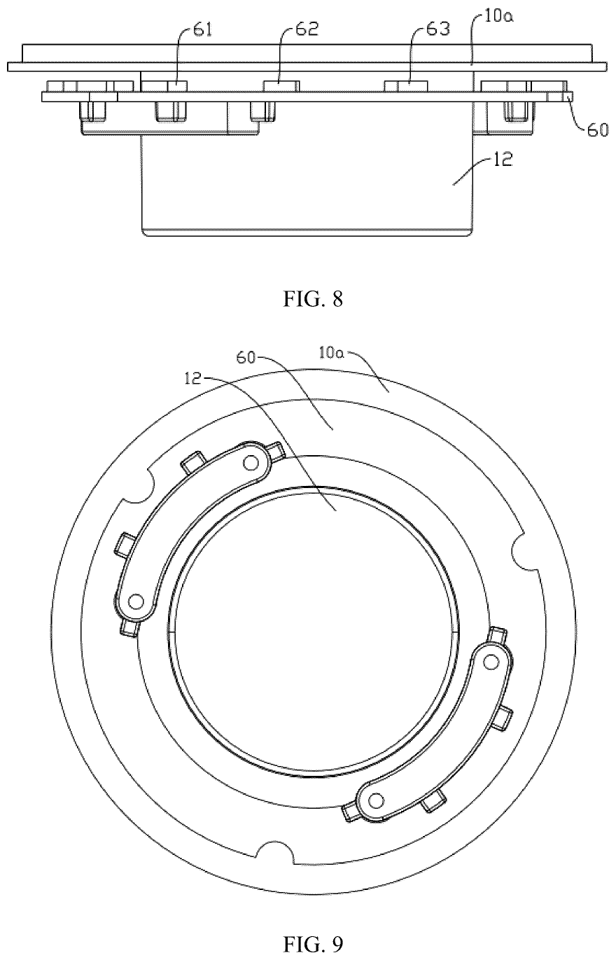

FIG. 8 is a front side schematic diagram of a boss and light-emitting pieces according to one embodiment of the present disclosure. FIG. 9 is a bottom schematic diagram of the boss according to one embodiment of the present disclosure.

As shown in FIGS. 2, 4, 8, and 9, light-emitting pieces are embedded on the top portion of the base 20 and are disposed around the mounting opening 21. The light-emitting pieces 61-63 labeled in the drawings are for illustrative purposes only and do not limit a specific number of the light-emitting pieces. The light-emitting pieces 61-63 are configured to emit light toward the first space 111.

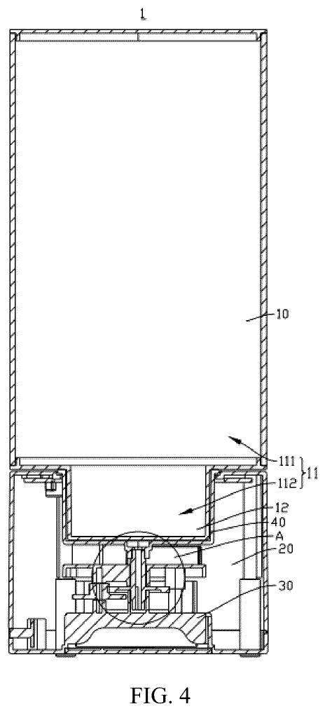

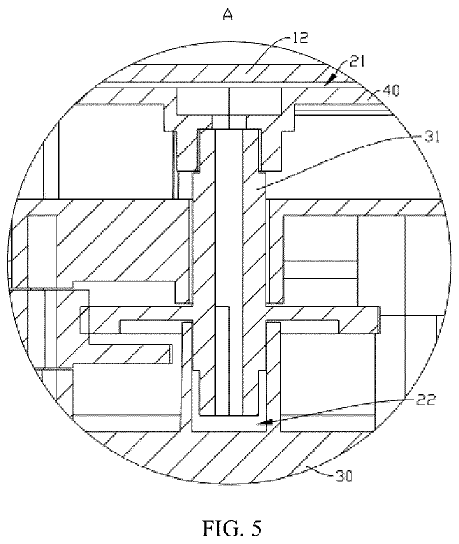

The light-emitting pieces 61-63 are fixed on a light-emitting fixing piece 60. The light-emitting fixing piece 60 is fixed on the top portion (not shown in the drawings) of the base 20. Therefore, the light-emitting pieces 61-63 are embedded in the outer periphery of the mounting opening 21. Optionally, the bottom portion 10a of the housing is made of the light-transmitting material. As shown in FIGS. 8 and 9, a bottom surface of the light-emitting fixing piece 60, a bottom surface of the boss 12, and the bottom portion 10a of the housing are circular surfaces, and a radius of the bottom surface of the light-emitting fixing piece 60 is greater than a radius of the bottom surface of the boss 12, and the radius of the bottom surface of the light-emitting fixing piece 60 is less than a radius of the bottom portion 10a of the housing. Therefore, when the light-emitting pieces 61-63 emit light in an upward direction, the first space 111 shown in FIG. 4 is illuminated, so that the main body of the display piece is clearly displayed in a dim environment.

The light emitting pieces 61-63 are small light emitting components such as light emitting diodes, electronic fluorescent lamps, and organic light emitting diodes.

Optionally, at least part of the light-emitting pieces are configured to alternately emit light of at least two colors.

For instance, the light-emitting piece 61 and the light-emitting piece 62 emit red light and blue light alternately. When the light-emitting piece 61 emits the red light, the light-emitting piece 62 emits the blue light. When the light-emitting piece 61 alternates from emitting the red light to emitting the blue light, the light-emitting piece 62 alternates from emitting the blue light to emitting the red light, thereby creating a visual effect that the light-emitting piece 61 and the light-emitting piece 62 also rotate along with the rotating display device, thereby increasing the interest of the rotating display device 1.

In order to reduce a power consumption of the rotating display device 1, as shown in FIG. 1, three control buttons are disposed on the base 20. The three control buttons comprise a first button 241, a second button 242, and a third button 243. The first button 241 is configured to control a total power supply of the rotating display device 1. The second button 242 is configured to control an operation of the rotating drive assembly 30. The third button 243 is configured to control an operation of the light-emitting pieces 61-63. After operating the first button 241, the second button 242 is operated, and at this time, the rotating driving assembly 30 starts to work. After operating the first button 241, the third button 243 is operated, and at this time, the light-emitting pieces 61-63 start to work, thereby avoiding a situation where the rotating display device 1 is always in a working state and consumes power after the second button 242 or the third button 243 is accidentally touched.

When assembling the rotating display device 1 of the embodiment of the present disclosure, it is only necessary to fix the rotating driving assembly 30 inside the base 20, then extend the boss 12 into the mounting opening 21 to be fixedly connected to the rotating driving assembly 30, and fix the display piece in the second space 112 defined inside the boss 12, so as to complete the assembly of the rotating display device 1, and a whole assembly process is relatively easy.

In addition, the rotating display device 1 in the embodiment of the present disclosure drives the boss 12 to rotate through the rotating driving assembly 30, thereby driving the housing 10 and the display piece to rotate together, which realizes synchronous driving of the rotation of the housing 10 and the display piece.

In the embodiment of the present disclosure, the first space 111 accommodates the main body of the display piece, and the second space 112 accommodates the bottom portion of the display piece, so that the bottom portion of the display piece is shielded by the portion of the housing forming the second space, and the main body of the display piece is allowed to be displayed through the portion of the housing made of the light-transmitting material that forms the first space 111, so that only the main body of the display piece located in the first space is displayed. In addition, the boss 12 acts as the transmission piece of the output shaft 331 of the rotating driving assembly 30, driving the housing 10 and the display piece to rotate, and at the same time, the second space 112 of the boss 12 shields the bottom portion of the display piece, which simplifies the structure of the rotating display device 1. Therefore, the rotating display device 1 is simple in structure, low in design cost, and easy to produce.

The above-mentioned embodiments are only configured to illustrate technical solutions of the present disclosure, but not to limit the present disclosure. Although the present disclosure has been described in detail with reference to the foregoing embodiments. It should be understood that those of ordinary skill in the art are still able to modify the technical solutions described in the foregoing embodiments, or equivalently replace some of the technical features in the foregoing embodiments; and these modifications or replacements do not make the essence of the corresponding technical solutions deviate from spirit and scope of the technical solutions of the embodiment of the present disclosure, which shall be comprised in the protection scope of the present disclosure. In particular, as long as there is no structural conflict, all the technical features mentioned in the embodiments may be combined in any manner. The present disclosure is not limited to the specific embodiments disclosed herein, but comprises all technical solutions falling within the scope of the claims.

What is claimed is:

1. A rotating display device, comprising:
a housing;
a base; and
a rotating driving assembly;
wherein an accommodating space is defined in the housing, the accommodating space comprises a first space and a second space communicated with the first space, at least a portion of the housing defining the first space is made of a light-transmitting material, a boss is disposed at a bottom portion of the housing, the second space is defined inside the boss, the first space is configured to accommodate a main body of a display piece, and the second space is configured to accommodate a bottom portion of the display piece;
wherein a mounting opening is defined in a top portion of the base, the rotating driving assembly is disposed in the base, the boss extends into the mounting opening to be fixedly connected to an output shaft of the rotating driving assembly, and the rotating driving assembly is configured to drive the housing to rotate relative to the base, so as to drive the display piece to rotate.

2. The rotating display device according to claim 1, wherein the rotating display device further comprises a mounting base, the mounting base is disposed in the base and is in a box shape with an opening facing the mounting opening, a bottom portion of the mounting base is fixedly connected to the output shaft of the rotating driving assembly, and the boss is inserted and fixed inside the mounting base.

3. The rotating display device according to claim 2, wherein a limiting groove is defined in a center of an inner bottom surface of the base, positioning columns are disposed on the inner bottom surface of the base, and the positioning columns are disposed around the limiting groove;
wherein the rotating driving assembly comprises a rotating column, a transmission gear set, and a driving piece;
wherein a first end of the rotating column is rotatably disposed in the limiting groove, and a second end of the rotating column is fixed to a center of a bottom surface of the mounting base;
wherein the transmission gear set comprises an input gear, transmission gears and an output gear; wherein the input gear, the transmission gears, and the output gear are sequentially engaged, the input gear and the transmission gears are respectively rotatably sleeved on the positioning columns, and the output gear is fixedly sleeved on the rotating column;
wherein the driving piece comprises the output shaft, the output shaft is connected to the input gear and is configured to drive the input gear to rotate, transmission gears rotate to drive the output gear to rotate, the output gear rotates to drive the rotating column to rotate, and the rotating column rotates to drive the mounting base to rotate.

4. The rotating display device according to claim 3, wherein the driving piece is horizontally disposed in the base, and the output shaft is rotatably and vertically connected to the input gear.

5. The rotating display device according to claim 3, wherein top ends of the positioning columns are fixedly connected to a support platform;
wherein a through hole is defined in the support platform, the mounting base is disposed on the support platform, the rotating column passes through the through hole and is fixed in the center of the bottom surface of the mounting base, and the rotating column is configured to drive the mounting base to rotate on the support platform.

6. The rotating display device according to claim 5, wherein rims are disposed on a top surface of the support platform, the rims have a same length and are centrosymmetric, the mounting base is disposed on the rims, and the rotating column is configured to drive the mounting base to rotate on the rims.

7. The rotating display device according to claim 1, wherein light-emitting pieces are embedded on the top portion of the base and are disposed around the mounting opening, and the light-emitting pieces are configured to emit light toward the first space.

8. The rotating display device according to claim 7, wherein at least part of the light-emitting pieces are configured to alternately emit light of at least two colors.

9. The rotating display device according to claim 1, wherein the bottom portion of the housing is detachably connected to a side wall of the housing, and/or
a top surface of the housing is detachably connected to the side wall of the housing.

10. The rotating display device according to claim 1, wherein the accommodating space is further configured to hold a transparent liquid, and the display piece is submerged in the transparent liquid.
